(19) United States
(12) Patent Application Publication
(10) Pub. No.: US 2005/0285266 A1
(43) Pub. Date: Dec. 29, 2005

(54) Arrangement for increasing the reliability of substrate-based BGA packages

(76) Inventors: Martin Reiss, Dresden (DE); Anton Legen, Muenchen (DE); Manuel Carmona, Barcelona (ES); Carsten Bender, Dresden (DE)

Correspondence Address: SLATER & MATSIL LLP, 17950 PRESTON ROAD, SUITE 1000, DALLAS, TX, 75252, US

(21) Appl. No.: 11/155,318

(22) Filed: Jun. 17, 2005

(30) Foreign Application Priority Data
Jun. 18, 2004 (DE) 10 2004 029 584.0

(51) Int. Cl. H01L 23/48; H01L 21/44

(52) U.S. Cl. 257/738; 257/780; 257/778; 438/108; 438/613

(57) ABSTRACT

An arrangement increases the reliability of substrate-based Ball-Grid-Array (BGA) packages, with a die (chip) that is mounted on a substrate and electrically connected to interconnects of the substrate and for which the substrate is provided with solder balls arranged in a predetermined grid. The arrangement is particularly simple to realize and effective for increasing the reliability of substrate-based Ball-Grid-Array packages. This is achieved by a laminate layer provided with openings for receiving the solder balls at the positions of ball pads being laminated on the side of the substrate that is provided with the interconnects.

This application claims priority to German Patent Application 10 2004 029 584.0, which was filed Jun. 18, 2004, and is incorporated herein by reference.

### TECHNICAL FIELD

The invention relates to an arrangement for increasing the reliability of substrate-based Ball-Grid-Array (BGA) packages, with a die (chip), which is mounted on a substrate and electrically connected to interconnects of the substrate and for which the substrate is provided with solder balls arranged in a predetermined grid.

### BACKGROUND

In substrate-based Ball-Grid-Array packages (BGA packages), the reliability of the package soldered on a printed circuit board (PCB) (2^{nd}-level reliability) is a problem. Faults can be found to occur in particular in thermal cycling, that is to say passing repeatedly through considerable temperature changes, of the soldered-on packages, caused by failure due to fatigue ruptures of the solder connections, i.e., the solder balls.

Such a package comprises, for example, a substrate on which a die is attached by chip bonding, the substrate is provided with a central bonding channel, through which wire bridges, which are drawn from the bonding pad of the die to contact islands on the substrate, are electrically connected to the substrate, and in which an array of solder balls is arranged on the side of the substrate facing away from the die. The solder balls of which array are electrically connected respectively by means of ball pads to interconnects on the substrate.

Furthermore, to protect the sensitive wire bridges, the bonding channel is filled with a casting compound and the side of the substrate with the die is encapsulated with a molding compound for its protection.

The fatigue of the solder connections in thermal cycling of the module is caused essentially by the different thermal expansion behavior of the package and the PCB (Printed Circuit Board) during the thermal cycling and also by a lack of flexibility of the substrate.

The thermomechanical stresses induced in the thermal cycling are relieved at the weakest point in the package-PCB assembly, the weakest point generally being formed by the solder connections between the PCB and the package.

In order to minimize this thermomechanical loading in the thermal cycling, and thereby achieve an improvement in reliability, a die-compensating layer was provided as a possible variant. This die-compensating layer was arranged between the die and the substrate.

Other possibilities for increasing the reliability are, for example, to adapt the thickness of the die, for example to thin the die, which does indeed lead to positive effects but is not adequate.

An improvement in the reliability of the solder connections can also be achieved in principle by increasing the amount of solder used, in that the solder ball diameter is increased and, if appropriate, a reduction is additionally made in the notching of the solder at the transition between the solder ball and the solder resist mask opening on the substrate. However, the increase in the solder ball diameter in the BGA device is only possible to a restricted extent and is limited by the predetermined pitch of the solder balls. In the case of diameters of the solder balls above a component-specific limit value, short-circuits can occur between the solder balls.

The substrates are produced in the customary way from glass fiber laminates with epoxy resin binders, on the underside of which there is generally laminated a layer r, which is patterned by customary patterning methods (photolithography together with methods) in such a way as to form interconnects, which are provided with ball pads for g and electrically contacting the solder balls. The interconnects are covered in the ry way with a layer of a solder resist, while the ball pads are not covered with solder ut are provided with a suitable surface protection (for example an organic protective an additional metallization, for example a nickel-gold layer).

### SUMMARY OF THE INVENTION

Embodiments of the invention provide an arrangement that is particularly simple to realize and effective for increasing the reliability of substrate-based Ball-Grid-Array packages.

Starting from an arrangement of the type stated at the beginning, aspects of the invention provide a laminate layer provided with openings at the positions of the ball pads being laminated on the side of the substrate that is provided with the interconnects.

In a first refinement of the invention, the additional laminate layer comprises a polyimide film.

To increase the reliability of substrate-based Ball-Grid-Array packages, a die (chip) is mounted on a substrate and electrically connected to interconnects of the substrate. A substrate is provided with solder balls arranged in a predetermined grid that are respectively connected to a ball pad on the substrate. A first laminate layer of a single-ply substrate, comprising one or more layers of glass fiber fabric and with a patterned copper laminate layer, is bonded together with a second laminate layer by pressing. The second laminate layer is provided with openings at the positions of the ball pads.

In a continuation of the invention, the openings are formed in such a way that they open in a funnel-shaped manner.

Finally, it is provided that the orientation of the glass fibers of the second substrate layer is turned by 90° with respect to the first substrate layer.

According to embodiments of the invention, a further laminate layer, which is preferably opened in a funnel-shaped manner at the positions of the ball pads, is laminated onto the substrate bearing interconnects. The funnel-shaped opening in the additional laminate layer makes it possible to increase significantly the amount of solder metal available per solder ball and to reduce the constriction/notching of the solder contact without having to increase the diameter of the forming solder contact to a critical value.

Applying the additional laminate layer with the funnel-shaped openings for receiving the solder balls allows the solder volume available for the solder contact to be increased significantly. The result is an improvement in the reliability of the solder connection in thermal cycling.

If a funnel-shaped opening is provided in the additional laminate layer, this reduces the stress acting on the solder connection in thermal cycling that is otherwise produced by the rolling of the solder ball onto a firm edge of the solder resist and can make the solder ball snap off.

### DESCRIPTION OF THE DRAWINGS

The invention is explained in more detail below on the basis of an exemplary ent. In the associated drawings:

FIG. 1 shows the schematic construction of a board-on-chip BGA package with an al laminate layer on the substrate; and

FIG. 2 shows a view of a detail of a substrate modified according to the invention, nd substrate layer having here an opening angle of greater than 90° over the contact pads her stress reduction.

The following list of reference symbols can be used in conjunction with the figures:

| | |
|---|---|
| 1 | BOC package |
| 2 | substrate |
| 3 | die/chip |
| 4 | chip adhesive |
| 5 | mold cap |
| 6 | ball pad |
| 7 | solder ball |
| 8 | bonding channel |
| 9 | casting compound |
| 10 | laminate layer |
| 11 | opening |
| 12 | solder resist |

### DETAILED DESCRIPTION OF ILLUSTRATIVE EMBODIMENTS

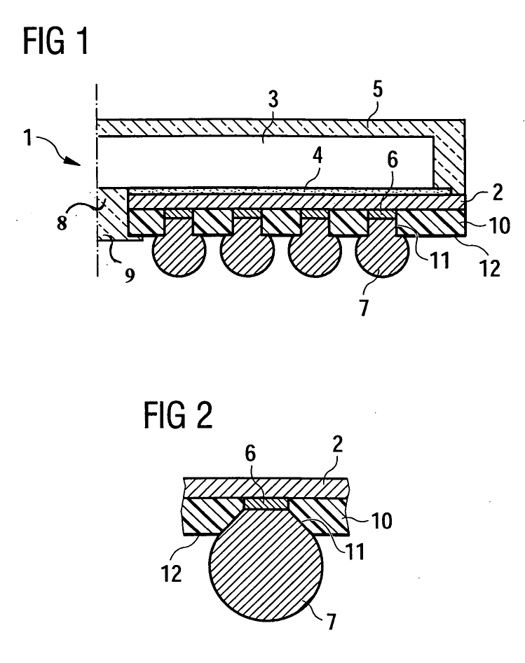

In FIG. 1, one half of an FBGA package, to be precise a board-on-chip BGA package 1 (BOC or board-on-chip package), is represented. This BOC package 1 comprises a substrate 2, on which a die 3 is attached by means of a chip adhesive 4. The back side of the die 3, including parts of the substrate 2, is provided with a mold cap 5 to protect the die 3.

Arranged in an array on the side of the substrate 2 that is opposite from the die 3 are ball pads 6 for receiving and electrically contacting solder balls 7. These ball pads 6 are connected by means of interconnects (not represented) to contact pads next to a central bonding channel 8 in the substrate 2, which for their part are electrically connected by means of wire bridges through the bonding channel 8 to bonding pads on the die 3. The bonding channel 8 is filled with a casting compound 9 to protect the wire bridges.

In order to achieve an increase in the solder volume, an additional laminate layer 10, provided with openings 11 over the ball pads 6 into which the solder balls 7 are inserted, is applied on the ball side of the substrate 2. The additional laminate layer 10 is provided in the customary way with a solder resist 12, which leaves the openings 11 clear.

A “single-ply” substrate 2 is formed by one or more layers of glass fiber fabric, which are encapsulated with a matrix material (resin), generally epoxy resin. The additional laminate layer 10 can be produced by simple pressing with the substrate 2 at an elevated temperature.

A polyimide film or the like, for example a solder resist mask, may be applied as an additional laminate layer 10 to the substrate 2.

In FIG. 2, a view of a detail of the substrate 2 prepared with the additional laminate layer 10 is represented, the openings 11 in the laminate layer 10 opening with respect to the solder ball 7 at an angle greater than 90°, whereby a further stress reduction is achieved.

Applying the additional laminate layer 10 with openings corresponding to the arrangement of the solder balls 7 allows the solder volume available for the solder contact to be increased, whereby the reliability in thermal cycling is increased.

The patterning of the additional laminate layer 10 corresponding to FIG. 2 can additionally reduce the stress acting on the solder connections during the temperature cycling that is otherwise produced by the rolling of the solder balls 7 onto a firm edge of the substrate 2.

1. An electronic component comprising:
a substrate including interconnects, the substrate further including solder pads on a lower surface, respective ones of the interconnects being electrically coupled to respective ones of the solder pads, the substrate including a laminate layer on a second surface, the laminate layer including openings to receive solder balls at the positions of the solder pads; and
a die mounted on the substrate and electrically coupled to the interconnects of the substrate.

2. The electronic component of claim 1, wherein the laminate layer comprises a polyimide film.

3. The electronic component of claim 1, wherein the interconnects are formed on the lower surface, the laminate layer overlying the interconnects.

4. The electronic component of claim 3, wherein the substrate further includes a bonding channel, wherein the die is electrically coupled to the substrate through bond wire connections that extend through the bonding channel.

5. The electronic component of claim 4, wherein the openings comprise funnel-shaped openings.

6. The electronic component of claim 1, wherein the openings comprise funnel-shaped openings.

7. An electronic component comprising:
a substrate including a plurality of ball pads arranged in a predetermined grid, the substrate comprising a first laminate layer of a single-ply substrate including one or more layers of glass fiber fabric and with a patterned copper laminate layer, the substrate further including a second laminate layer bonded on the first laminate layer, the second laminate layer being provided with openings for receiving solder balls at the positions of the ball pads; and
a die mounted on the substrate and electrically coupled to the interconnects of the substrate.

8. The electronic component of claim 7, wherein the openings comprise funnel-shaped openings.

9. The electronic component of claim 7, wherein an orientation of glass fibers of the second laminate layer are turned by about 90° with respect to glass fibers of the glass fiber fabric.

10. The electronic component of claim 7, wherein the second laminate layer comprises a polyimide film.

11. The electronic component of claim 7, wherein the substrate further includes a bonding channel, wherein the die is electrically coupled to the substrate through bond wire connections that extend through the bonding channel.

12. The electronic component of claim 11, wherein the openings comprise funnel-shaped openings.

13. A method of assembling a semiconductor component, the method comprising:
providing a substrate that includes a plurality of balls pads on a surface of the substrate;
forming a laminate layer over the surface of the substrate, the laminate layer including openings to expose the ball pads;
attaching solder balls to the ball pads, the solder balls fitting in the openings;
mounting a semiconductor die onto the substrate; and
electrically coupling the semiconductor die to the ball pads of the substrate.

14. The method of claim 13, wherein forming a laminate layer comprises pressing the laminate layer onto the substrate.

15. The method of claim 13, wherein forming a laminate layer comprises forming a polyimide film over the surface of the substrate.

16. The method of claim 13, wherein the laminate layer comprises a plurality of glass fibers.

17. The method of claim 16, wherein the substrate comprises a plurality of glass fibers, wherein the glass fibers of the substrate are oriented by about 90° relative to the glass fibers of the laminate layer.

18. The method of claim 13, wherein the openings comprise funnel-shaped openings.

19. The method of claim 13, wherein mounting the semiconductor die onto the substrate comprises mounting the semiconductor die onto a second surface of the substrate, the second surface opposite the surface, and wherein electrically coupling the semiconductor die comprises wire-bonding bond pads on the semiconductor die to bond pads on the surface of the substrate, the wire-bonding causing wire bonds to extend through a bond channel in the substrate.

20. The method of claim 19, wherein the openings comprise funnel-shaped openings.
